(19) United States
(12) Patent Application Publication
(10) Pub. No.: US 2006/0054953 A1
(43) Pub. Date: Mar. 16, 2006

(54) Memory devices having a resistance pattern and methods of forming the same

(76) Inventors: Suk-Joon Son, Seoul (KR); Jin-Taek Park, Gyeonggi-do (KR); Jong-Ho Park, Seoul (KR)

Correspondence Address: Robert W. Glatz;Myers Bigel Sibley & Sajovec, P.A., P.O. Box 37428, Raleigh, NC, 27627, US

(21) Appl. No.: 11/222,196

(22) Filed: Sep. 8, 2005

(30) Foreign Application Priority Data
Sep. 15, 2004 (KR) 2004-73886

(51) Int. Cl. G03G 15/02; H01L 29/94

(52) U.S. Cl. 257/296; 430/57.7

(57) ABSTRACT

Memory devices include a semiconductor substrate and a device isolation layer in the substrate and defining a cell region and a resistance region. A resistance pattern is disposed on the device isolation layer in the resistance region. An interlayer insulating layer is on the resistance pattern and a resistance contact hole with a contact plug therein extends through the interlayer insulating layer and exposes the resistance pattern. A conductive pad pattern is interposed between the resistance pattern and the device isolation layer that is electrically connected to the resistance pattern. The conductive pad pattern is positioned between the resistance contact hole and the device isolation layer and has a planar area greater than a planar area of the resistance pattern exposed by the resistance contact hole. The conductive pad pattern and the resistance pattern define a resistor of the memory device having a greater thickness in a region including the conductive pad pattern.

### CROSS-REFERENCE TO RELATED APPLICATIONS

This patent application is related to and claims priority from Korean Patent Application 2004-73886, filed on Sep. 15, 2004, the contents of which are hereby incorporated by reference in their entirety.

### BACKGROUND OF THE INVENTION

The present invention relates to semiconductor (integrated circuit) devices and methods for forming the same, and more particularly, to non-volatile memory devices and methods for forming the same.

Semiconductor integrated circuits may include active devices, such as transistors, and passive devices, such as resistors. A resistor may be included, for example, to control the amount of current flow or to perform other functions in the semiconductor integrated circuit device.

A non-volatile memory device type of semiconductor integrated circuit is designed to retain stored data even when a power supply thereto is cut off. An electronically erasable programmable read only memory (EEPROM) device that stores data in a floating gate is one known type of non-volatile memory device. Typically, the floating gate in such devices is formed of a doped polysilicon.

In an EEPROM device having a floating gate, methods for forming a resistor using doped polysilicon in order to form a floating gate have been suggested. FIGS. 1 through 4 are schematic cross-sectional views illustrating a method for forming a conventional resistance pattern. In FIGS. 1 through 4, reference numerals “50” and “51” indicate a cell region and a resistance region, respectively.

Referring now to FIG. 1, a device isolation layer (3) is formed at a predetermined region of a semiconductor substrate (1). The device isolation layer (3) defines an active region of the cell region (50), and is shown as formed in the resistance region (51).

A tunnel oxide layer (5) and a doped polysilicon layer are sequentially formed on an entire surface of the semiconductor substrate (1). As shown in FIG. 1, a preliminary floating gate (7a) is formed in the cell region (50) and a resistance pattern (7b) is formed in the resistance region (51) by patterning the doped polysilicon layer. The preliminary floating gate (7a) is formed on an active region of the cell region (50), and the resistance pattern (7b) is formed on a device isolation layer (3) of the resistance region (51).

An intergate dielectric layer (9), a polycide layer (11) and a nitride layer (13) are sequentially formed on an entire surface of the semiconductor substrate (1). The polycide layer (11) is a stacked layer of doped polysilicon and tungsten silicide.

Referring to FIG. 2, a photosensitive film pattern (15) is formed on the semiconductor substrate (1). The photosensitive film pattern (15) covers the nitride layer (13) in the cell region (50). The nitride layer (13) in the resistance region (51) remains exposed. The nitride layer (13) and the polyside layer (11) in the resistance region (51) are removed by anisotropic etching using the photosensitive film pattern (15) as a mask. The resistance pattern (7b) may be exposed by removing the intergate dielectric layer (9) in the resistance region (51).

Referring to FIG. 3, the photosensitive film pattern (15) is removed. A floating gate (17), a gate interlayer dielectric pattern (9a), a control gate electrode (11a and a hard mask pattern (13a), which are sequentially stacked on the active region, are then formed by consecutively patterning the nitride layer (13), the polycide layer (11), the gate interlayer dielectric layer (9) and the preliminary floating gate (7a) in the cell region (50). A source/drain region (19) is formed in the active region at both sides of the control gate electrode (11 a) by selectively implanting impurity ions.

An interlayer insulating layer (21) is formed on an entire surface of the semiconductor substrate (1). In order to reduce a step difference between regions of the semiconductor substrate (1), a process for planarizing a top surface of the interlayer insulating layer (21) may be performed. A bit line contact hole (23a) and a resistance contact hole(s) (23b) are simultaneously formed by patterning the interlayer insulating layer (21). The bit line contact hole (23a) exposes the source/drain region (19) and the resistance contact hole(s) (23b) expose the resistance pattern (7b). The resistance contact hole(s) (23b) expose both edges of a top surface of the resistance pattern (7b), respectively.

An insulating spacer (25) is formed on the sidewalls of the contact holes (23a, 23b). A bit line plug (27a) for filling the bit line contact hole (23a) and a resistance plug(s) (27b) for filling the resistance contact hole (23b) are formed. A bit line (28a) connected with the bit line plug (27a) and an interconnection (28b) connected with the resistance plug(s) (23b) are formed on the interlayer insulating layer (21).

For high integration density semiconductor devices, a distance between the bit line contact hole(s) (23a) and the gates (17, 11a may be decreased. Accordingly, the insulating spacers (25) in the active region may be formed to insulate the gates (17, 11a) and the bit line plug (27a).

In the above described method for forming a conventional non-volatile memory device, even though there is an etch selectivity between the interlayer insulating layer (21) and the resistance pattern (7b), the resistance pattern (7b) may be etched due to an overetch etc., when the contact holes (23a, 23b) are formed. Especially, for high integration density semiconductor devices, a thickness of the resistance pattern (7b) is generally decreased as a thickness of the floating gate (17) is decreased. Accordingly, when the contact holes (23a, 23b) are formed, the resistance pattern 7b may be penetrated by due to an increased amount of etching of the resistance pattern 7b. Furthermore, when a top surface of the interlayer insulating layer (21) is planarized in order to reduce a step difference between regions, the bit line contact hole (23a) may deepen in comparison with the resistance contact hole (23b). As a result, when the contact holes (23a, 23b) are formed, the etching amount of the resistance pattern (7b) may be increased. Therefore, a margin for the etching process may be greatly reduced for forming the contact holes (23a, 23b).

Possible problems when the resistance pattern (7b) is overly etched and penetrated will now be described with reference to FIG. 4. FIG. 4 is a cross-sectional view to describe problems relating to a conventional method for forming a non-volatile memory device.

Referring to FIG. 4, when contact holes (23a, 23b′) are formed, a resistance contact hole (23b′) may penetrate a resistance pattern 7b to expose the device isolation layer (3). At this time, the resistance pattern (7b) is exposed on a lower sidewall of the resistance contact hole (23b′). For securing insulation, insulating spacers (25, 25′) are formed on the sidewalls of the contact holes (23a, 23b′). Bit line and resistance contact plugs (27a, 27b′) are then formed to fill the bit line and resistance contact holes (23a, 23b′), respectively. At this time, an insulating spacer (25′) formed on a sidewall of the resistance contact hole (23b′) covers the resistance pattern (7b) exposed on a lower sidewall of the resistance contact hole(s) (23b′). Accordingly, the resistance plug(s) (27b′) and the resistance pattern (7b) are insulated by the insulating spacer(s) (25′). As a result, the resistance pattern (7b) and the interconnections (28b) are insulated from each other, thereby degrading the quality of the non-volatile memory device.

### SUMMARY OF THE INVENTION

Embodiments of the present invention provide memory devices including a semiconductor substrate and a device isolation layer in the substrate and defining a cell region and a resistance region. A resistance pattern is disposed on the device isolation layer in the resistance region. An interlayer insulating layer is on the resistance pattern and a resistance contact hole with a contact plug therein extends through the interlayer insulating layer and exposes the resistance pattern. A conductive pad pattern is interposed between the resistance pattern and the device isolation layer that is electrically connected to the resistance pattern. The conductive pad pattern is positioned between the resistance contact hole and the device isolation layer and has a planar area greater than a planar area of the resistance pattern exposed by the resistance contact hole. The conductive pad pattern and the resistance pattern define a resistor of the memory device having a greater thickness in a region including the conductive pad pattern.

In some embodiments, the resistance contact hole includes a first contact hole having a first contact plug therein and a second contact hole displaced from the first contact hole and having a second contact plug therein. The conductive pad pattern includes a first region between the first contact hole and the device isolation layer and a separate second region between the second contact hole and the device isolation layer and the resistor has a smaller thickness in a region between the first and second region of the conductive pad pattern than in regions including the conductive pad pattern. The memory device further includes a first conductive interconnection extending on the interlayer insulating layer in the resistance region and electrically contacting the first contact plug and a second conductive interconnection extending on the interlayer insulating layer in the resistance region and electrically contacting the second contact plug. The memory device may be a non-volatile memory device including a floating gate in the cell region having a control gate electrode thereon with an etch protecting conductive layer therebetween and the etch protecting conductive layer and the conductive pattern may be formed in a same layer and the memory device may further include insulating spacers between sidewalls of the resistance contact holes and the contact plugs therein.

In other embodiments of the present invention, non-volatile memory devices include a device isolation layer in a substrate, the device isolation layer defining a cell region and having a resistance region thereon. A floating gate is on an active region of the cell region defined by the device isolation layer. A blocking dielectric pattern is on the floating gate and a control gate electrode is on the blocking dielectric pattern. The control gate electrode includes an etch protection pattern. A resistance pattern is disposed on the device isolation layer in the resistance region and a pad pattern is interposed between the resistance pattern and the device isolation layer and electrically connected to the resistance pattern. The pad pattern and the etch protection pattern are formed of the same material.

In further embodiments, the device includes a tunnel insulating layer and the tunnel insulating layer, the floating gate and the blocking dielectric pattern are sequentially stacked on the active region of the cell region defined by the device isolation layer. The control gate electrode includes the etch protection pattern, a gate conductive pattern and a low resistance pattern, which are sequentially stacked.

In other embodiments, an interlayer insulating layer covers a surface of the substrate in the cell region and the resistance region. A contact hole penetrates the interlayer insulating layer and exposes a portion of the resistance pattern that is disposed on the pad pattern. A plug fills the contact hole. A planar area of the pad pattern may be greater than a planar area of the portion of the resistance pattern that is exposed by the contact hole. Insulating spacer may be disposed on an inner sidewall of the contact hole. The resistance pattern may be formed of the same material as the gate conductive pattern. An insulating pattern may be interposed between the pad pattern and the device isolation pattern and the insulating pattern may be formed of the same material as the blocking dielectric pattern.

In yet other embodiments of the present invention, the substrate further includes a MOS region and the device further includes a gate insulating layer formed on a second active region defined by the device isolation layer in the MOS region. A MOS gate electrode is on the gate insulating layer. The MOS gate electrode includes a lower gate, an upper gate and a second low resistance pattern sequentially stacked on the gate insulating layer.

In further embodiments of the present invention, a first impurity doped layer is formed in the first active region at both sides of the control gate electrode and a second impurity doped layer is formed in the second active region at both sides of the MOS gate electrode. An interlayer insulating layer covers a surface of the substrate in the cell region, the MOS region and the resistance region. A MOS contact hole penetrates the interlayer insulating layer and exposes the second impurity doped layer. A MOS plug fills the MOS contact hole. A resistance contact hole penetrates the interlayer insulating layer and exposes a portion of the resistance pattern that is disposed on the pad pattern and a resistance plug fills the resistance contact hole. An insulating spacer may be disposed on an inner sidewall of the MOS contact hole and on an inner sidewall of the resistance contact hole. The resistance pattern, the gate conductive pattern and the upper gate may be formed of the same material. An insulating pattern may be interposed between the pad pattern and the device isolation layer and the insulating pattern may be formed of the same material as the blocking dielectric pattern.

In other embodiments of the present invention, methods for forming a non-volatile memory device include forming a device isolation layer in a substrate defining a cell region of the substrate and having a resistance region of the substrate thereon a floating gate is formed on an active region of the cell region defined by the device isolation layer. A blocking dielectric pattern is formed on the floating gate and a control gate electrode including an etch protection pattern is formed on the blocking dielectric pattern. A pad pattern is formed on the device isolation layer in the resistance region. The pad pattern is formed of the same material as the etch protection pattern. A resistance pattern is formed disposed on the device isolation layer in the resistance region. The resistance pattern covers the pad pattern and is electrically connected to the pad pattern.

In further embodiments of the present invention, forming the floating gate is preceded by forming a tunnel insulating layer on the active region of the cell region and forming the floating gate includes forming the floating gate on the tunnel insulating layer. Forming the control gate electrode includes forming the etch protection layer, forming a gate conductive pattern on the etch protection layer and forming a low resistance pattern on the gate conductive pattern. An interlayer insulating layer may be formed covering a surface of the substrate in the cell region and the resistance region. A contact hole may be formed penetrating the interlayer insulating layer and exposing a portion of the resistance pattern that is disposed on the pad pattern and a plug may be formed filling the contact hole. Forming the plug may be preceded by forming an insulating spacer on an inner sidewall of the contact hole.

In yet further embodiments of the present invention, forming the floating gate, forming the blocking dielectric pattern, forming the control gate electrode, forming the pad pattern and forming the resistance pattern includes forming a preliminary floating gate on the tunnel insulating layer, forming a blocking dielectric layer and an etch protection layer sequentially on the substrate and patterning the etch protection layer and the blocking dielectric layer to form an insulating pattern and the pad pattern sequentially stacked in the resistance region while leaving the blocking dielectric layer and the etch protection layer in the cell region. A gate conductive layer and a low resistance conductive layer are sequentially formed on the substrate. The gate conductive layer is exposed in the resistance region by selectively removing the low resistance conductive layer. The low resistance conductive layer, the gate conductive layer, the etch protection layer, the blocking dielectric layer and the preliminary floating gate of the cell region are sequentially patterned to form the floating gate, the blocking dielectric pattern and the control gate electrode and the resistance pattern is formed by patterning the exposed gate conductive layer in the resistance region.

In other embodiments of the present invention, forming the device isolation layer further includes forming a device isolation layer defining a MOS region of the substrate. A gate insulating layer is formed on a second active region defined by the device isolation layer in the MOS region and a MOS gate electrode is formed on the gate insulating layer. Forming the MOS gate electrode includes forming a lower gate on the gate insulating layer, forming an upper gate on the lower gate and forming a second low resistance pattern on the upper gate.

In yet other embodiments of the present invention, the methods further include forming a first impurity doped layer in the first active region at both sides of the control gate electrode and forming a second impurity doped layer in the second active region at both sides of the MOS gate electrode. An interlayer insulating layer is formed covering a surface of the substrate in the cell region, the MOS region and the resistance region. A MOS contact hole is formed penetrating the interlayer insulating layer and exposing the second impurity doped layer. A resistance contact hole is formed penetrating the interlayer insulating layer and exposing a portion of the resistance pattern that is disposed on the pad pattern. A resistance plug is formed filling the resistance contact hole and a MOS plug is formed filling the MOS contact hole. Forming the resistance plug and forming the MOS plug may be preceded by forming an insulating spacer on an inner sidewall of the resistance contact hole and on an inner sidewall of the MOS contact hole.

In further embodiments of the present invention, forming the floating gate, the blocking dielectric pattern, the control gate electrode, the MOS gate electrode, the pad pattern and the resistance pattern includes forming a preliminary floating gate on the first active region, forming a preliminary lower gate on the second active region, forming a blocking dielectric layer on the substrate and forming an etch protection layer on the blocking dielectric layer. The etch protection layer and the blocking dielectric layer are sequentially patterned to form a sequentially stacked insulation pattern and pad pattern on the device isolation layer in the resistance region and to remove the etch protection layer and the blocking dielectric layer in the MOS region while leaving the etch protection layer and the blocking dielectric layer in the cell region. A gate conductive layer is formed on the substrate and a low resistance conductive layer is formed on the gate conductive layer. The gate conductive layer in the resistance region is exposed by selectively removing the low resistance conductive layer. The low resistance conductive layer, the gate conductive layer, the etch protection layer, the blocking dielectric layer and the preliminary floating gate in the cell region are sequentially patterned to form the floating gate, the blocking dielectric pattern and the control gate electrode. The low resistance conductive layer, the gate conductive layer and the preliminary lower gate in the MOS region are sequentially patterned to form the MOS gate electrode and the exposed gate conductive layer in the resistance region is patterned to form the resistance pattern.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIGS. 1 through 3 are schematic cross-sectional views illustrating methods for forming a non-volatile memory device having a conventional resistance pattern.

FIG. 4 is a cross-sectional view illustrating problems caused when forming a conventional non-volatile memory device.

FIG. 5a is a plan view illustrating a non-volatile memory device in accordance with some embodiments of the present invention.

FIG. 5b is a cross-sectional view taken along the line I-I′ of FIG. 5a.

FIGS. 6a, 7a, 8a, 9a, 10a, 11a, 12a and 13a are plan views illustrating methods for forming a non-volatile memory device in accordance with some embodiments of the present invention.

FIGS. 6b, 7b, 8b, 9b, 10b, 11b, 12b and 13b are cross-sectional views taken along the line II-II′ of FIGS. 6a through 13a, respectively.

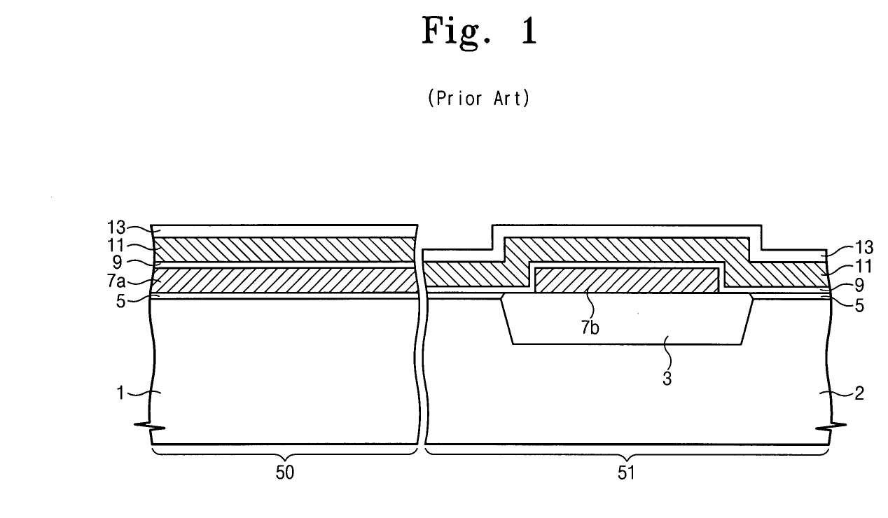

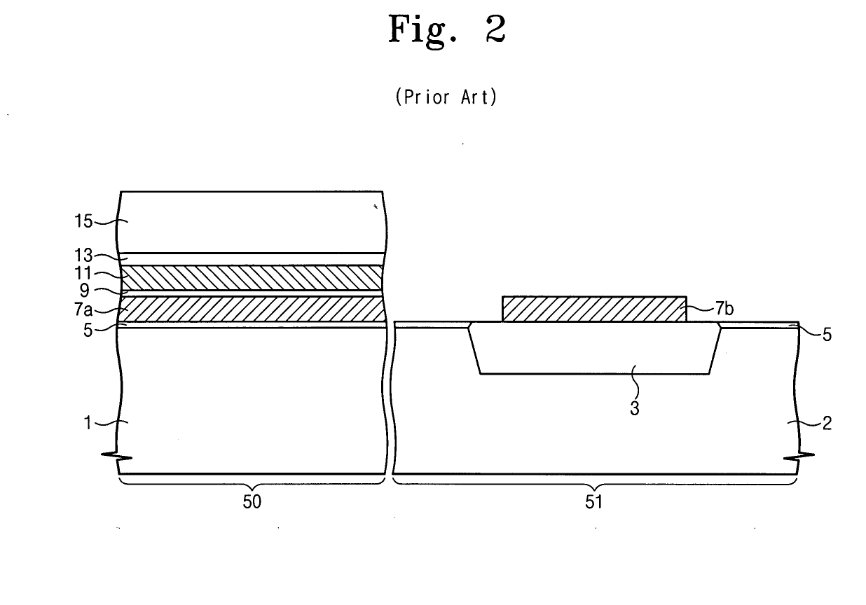

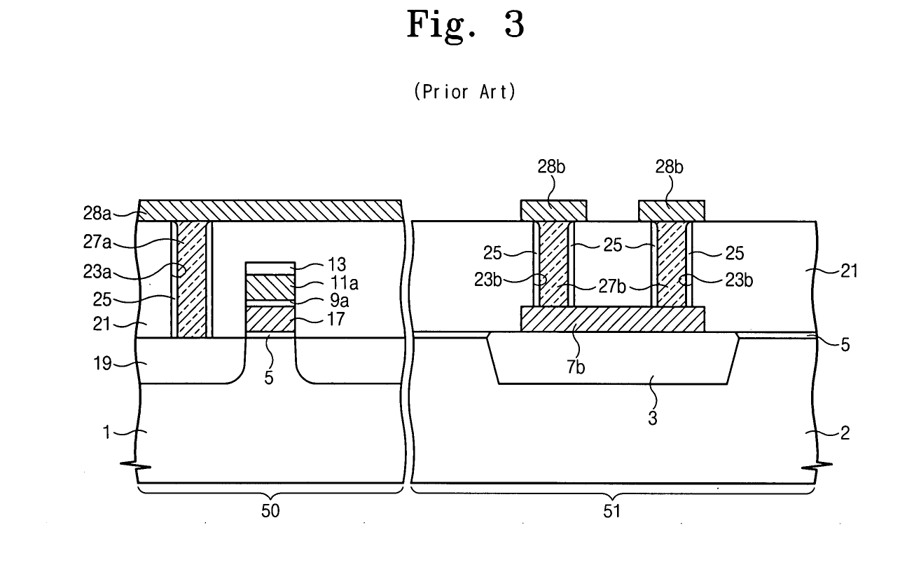

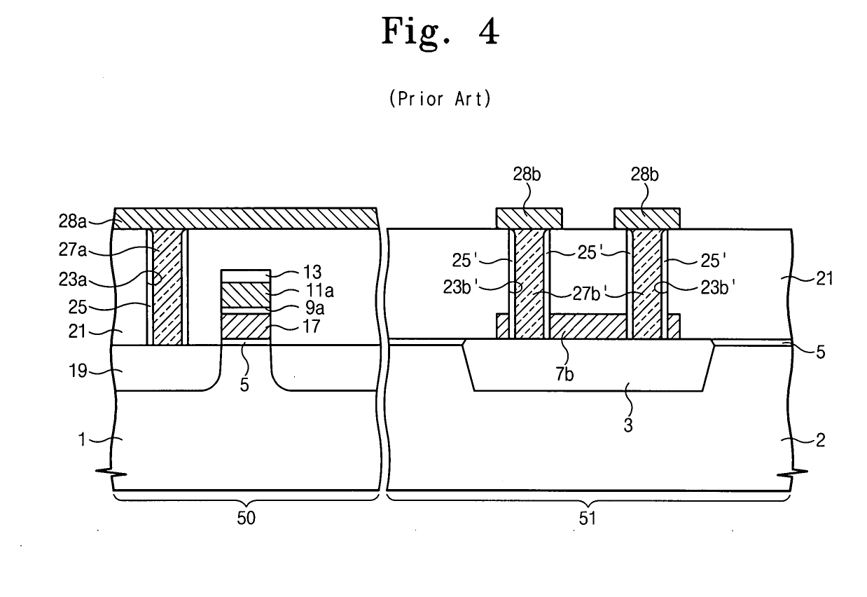

### DETAILED DESCRIPTION OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an etched region illustrated as a rectangle will, typically, have rounded or curved features. Thus, the regions illustrated in the figures are schematic in nature and their shapes are not intended to illustrate the precise shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

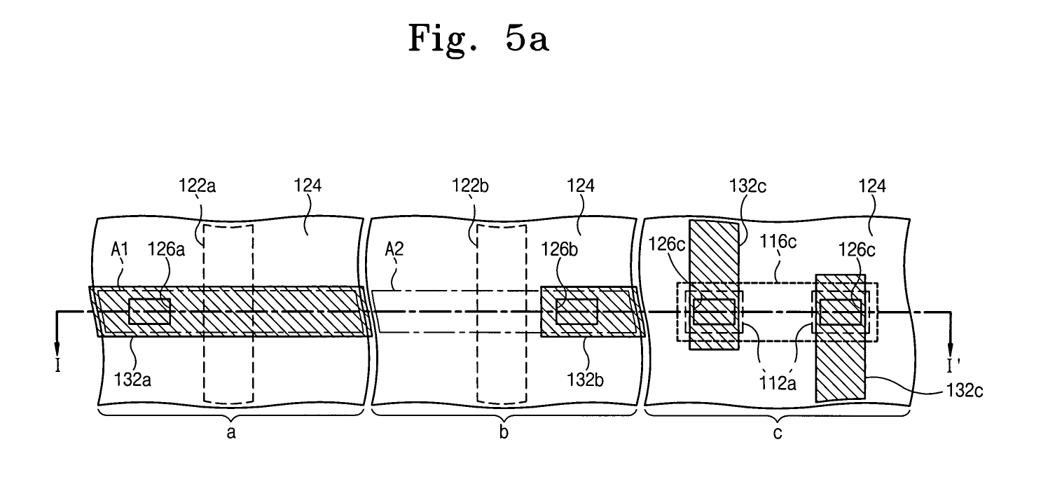

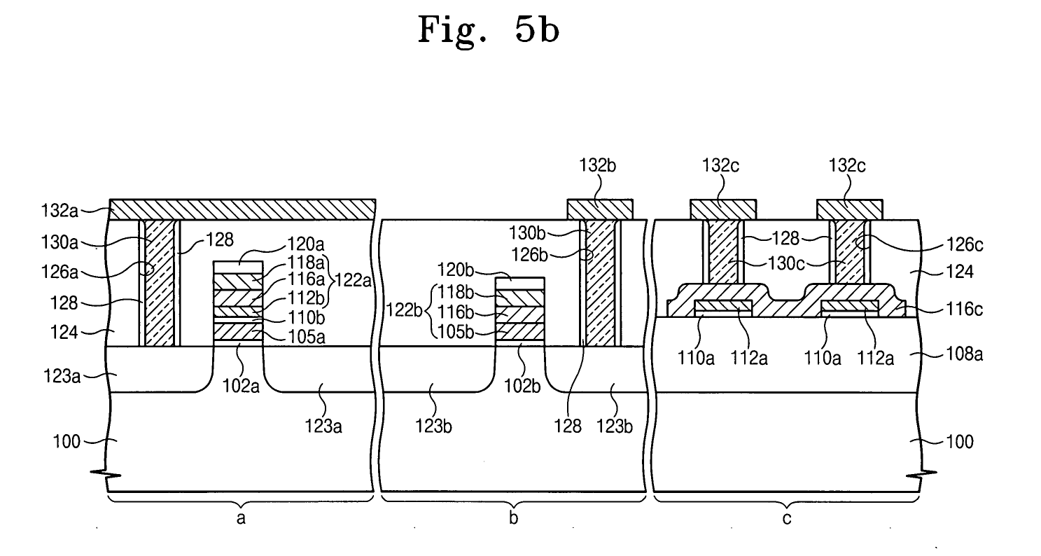

Various embodiments of the present invention will now be described with reference to the figures. FIG. 5 is a plan view illustrating a non-volatile memory device in accordance with some embodiments of the present invention and FIG. 5b is a cross-sectional view taken along the line I-I′ of FIG. 5a.

Referring to the embodiments of FIGS. 5a and 5b, the non-volatile memory device includes a device isolation layer (108a) disposed in a predetermined region of a semiconductor substrate (100) having a cell region (a), a MOS region (b) and a resistance region (c). The device isolation layer (108a) defines a first active region (A1) in the cell region (a), and the MOS region (b) defines a second active region (A2). The device isolation layer (108a) may be disposed on an entire region of the resistance region (c). The cell region (a) is a region where a floating gate storing data is disposed. The MOS region (b) is a region where a MOS transistor is formed. A MOS transistor of a peripheral circuit, a MOS transistor of a core region, and/or a selection transistor for selecting a cell may be disposed in the MOS region (b). The resistance region (c) is a region where a resistor is formed. The non-volatile memory device may include a NAND-type or a NOR-type flash memory device. In addition, the non-volatile memory device may be an EEPROM device of which a unit cell includes both the cell and MOS regions (a, b).

A tunnel insulating layer (102a) and a floating gate (105a) may be sequentially stacked on the first active region (A1). A control gate electrode (122a) crossing the first active region (A1) is disposed on the floating gate (105a). A blocking dielectric pattern (110b) is interposed between the control gate electrode (122a) and the floating gate (105a). A first capping pattern (120a) is disposed on the control gate electrode (122a). The control gate electrode (122a) is illustrated as including an etch protection pattern (112b), a gate conductive pattern (116a), and a first low resistance pattern (118a), which are sequentially stacked. A first impurity doped layer (123a) is disposed in the first active region (A1) at both sides of the control gate electrode (122a). The first impurity doped layer (123a) may have a lightly doped drain (LDD) structure and/or an extended source/drain structure.

The tunnel insulating layer (102a) may be formed of a thermal oxide layer, and the floating gate (105a) may be formed of doped polysilicon. The blocking dielectric pattern (110b) may be formed of an ONO layer. In addition, the blocking dielectric pattern (110b) may include a ferroelectric layer having a higher dielectric constant in comparison with an ONO layer. For example, the blocking dielectric pattern (110b) may include a metal oxide layer, such as an aluminum oxide layer and/or a hafnium oxide layer. The etch protection pattern (112b) may protect the blocking dielectric pattern (110b) during an etch process. The etch protection pattern (112b) in some embodiments is formed of doped polysilicon. In some embodiments, the gate conductive pattern (116a) is formed of doped polysilicon. The first low resistance pattern (118a) may be formed of a conductive material with a lower resistivity in comparison with doped polysilicon. In some embodiments, the first low resistivity pattern (118a) is formed of a conductive metal containing material. For example, the first low resistance pattern (118a) may be formed as a single layer or a combination layer selected from a metal layer (ex, tungsten and/or molybdenum, etc.), a conductive metal nitride layer (ex, titanium nitride and/or tantalum nitride, etc.) and/or a metal silicide layer (ex, tungsten silicide, cobalt silicide, nickel silicide, and/or titanium silicide). The first capping pattern (120a) may be formed of a silicon oxide layer, a silicon nitride layer and/or a silicon oxide nitride layer as an insulating layer.

A gate insulating layer (102b) and a MOS gate electrode (122b) are sequentially stacked on the second active region (A2). The MOS gate electrode (122b) crosses the second active region (A2). A second capping pattern (120b) is disposed on the MOS gate electrode (122b). The MOS gate electrode (122b) is illustrated as including a sequentially stacked lower gate (105b), an upper gate (116b) and a second low resistance pattern (118b).

The lower gate (105b) may be disposed on the second active region. A second impurity doped layer (123b) is disposed in the second active region (A2) at both sides of the MOS gate electrode (122b). The second impurity doped layer (123b) corresponds to a source/drain region of a MOS transistor. A gate spacer (not shown) may be disposed at both sidewalls of the MOS gate electrode (122b). A gate spacer may also be disposed at both sidewalls of the control gate electrode (122a). The second impurity doped layer (123b) may have an LDD structure and/or an extended source/drain structure.

The gate insulating layer (102b) may be formed of a thermal oxide layer. The gate insulating layer (102b) may have the same thickness as the tunnel insulating layer (102a). In other embodiments, the gate insulating layer (102b) may have a greater thickness than the tunnel insulating layer (102a). The lower gate (105b) may be formed of the same material as the floating gate (105a), and the upper gate (116b) may be formed of the same material as the gate conductive pattern (116a). The second low resistance pattern (118b) may be formed of the same material as the first low resistance pattern (118b).

The resistance pattern (116c) is shown disposed on a device isolation layer (108a) in the resistance region (c). A sequentially stacked insulating pattern (110a) and a pad pattern (112a) are interposed between the resistance pattern (116c) and the device isolation layer (108a). The pad pattern (112a) is disposed below an edge of the resistance pattern (116c), which covers a top surface and sidewalls of the pad pattern (112a). As shown, the pad pattern (112a) is disposed below both edges of the resistance pattern (116c). The pad pattern (112a) is electrically connected with the resistance pattern (116c). In some embodiments, the resistance pattern (116c) and the pad pattern (112a) are formed of doped polysilicon that is a conductive material that can be used as a resistor. The resistance pattern (116c) may be formed of the same material as the gate conductive pattern (116a) of the control gate electrode (122a), and the pad pattern (112a) may be formed of the same material as the etch protection pattern (112b) of the control gate electrode (122a). The insulating pattern (110a) may be formed of the same material as the blocking dielectric pattern (110b) in the cell region (a).

An interlayer insulating layer (124) for covering the above mentioned structures is shown disposed on an entire surface of the substrate (100). An etch stop layer (not shown) for covering the below mentioned structures may also be disposed below the interlayer insulating layer (124). An upper surface of the interlayer insulating layer (124) may be planarized. The interlayer insulating layer (124) may be formed of a silicon oxide layer. A cell contact hole (126a) exposes the first impurity doped layer (123a) by penetrating the interlayer insulating layer (124), and a MOS contact hole (126a) exposes the second impurity doped layer (123b) by penetrating the interlayer insulating layer (124). A resistance contact hole (126c) exposes the resistance pattern (I 16c) by penetrating the interlayer insulating layer (124). At this time, the resistance contact hole (126c) exposes the resistance pattern (116c) located on the pad pattern (112a). In other words, the resistance contact hole (126c) may expose edges of the resistance pattern (116c).

In some embodiments a planar area of the pad pattern (112a) is greater than that of the resistance contact hole (126c). In other words, the planar area of the pad pattern (112a) is greater than that of the region of the resistance pattern (116c) exposed by the resistance contact hole (126c).

Insulating spacers (128) are disposed at inner sidewalls of the contact holes (126a, 126b, 126c). The insulating spacers (128) may be formed of a silicon oxide layer, a silicon nitride layer and/or a silicon oxide nitride layer.

A cell plug (130a) fills the cell contact hole (126a) and a MOS plug (130b) fills the MOS contact hole (126b). A resistance plug(s) (130c) fills the contact hole(s) (126c). The plugs (130a, 130b, 130c) may be formed of the same conductive material. For example, the plugs (130a, 130b, 130c) may be formed of doped polysilicon and/or tungsten. The distances between the cell plug (130a) and the control gate electrode (122a) and/or between the MOS plug (130b) and the MOS gate electrode (122b) may be decreased in a high density device semiconductor substrate. Accordingly, the insulating spacer(s) (128) may be disposed on inner sidewalls of the contact holes (126a, 126b, 126c) for insulation between the cell plug (130a) and the control gate electrode (122a) and for insulation between the MOS plug (130b) and the MOS gate electrode (122b).

The cell contact hole (126a) and the cell plug (130a) may be omitted in some embodiments. For example, if the non-volatile memory device is a NAND-type non-volatile memory device, the cell contact hole (126a) and the cell plug (130a) may be omitted.

Interconnections (132a, 132b, 132c) electrically connected to the plugs (130a, 130b, 130c) are shown disposed on the interlayer insulating layer (124). A cell interconnection (132a) is illustrated as connected to the cell plug (130a) and a MOS interconnection (132b) is illustrated connected to the MOS plug (130b). The cell interconnection (132a) may be a bit line. Resistance interconnection(s) (132c) are connected to the resistance plug(s) (130c). The interconnections (132a, 132b, 132c) may be formed of a conductive material, such as doped polysilicon and/or tungsten.

In a non-volatile memory device having the above structure, the pad pattern (112a) is disposed below a resistance pattern (116c) in an area of the resistance pattern (116c) exposed by the resistance contact hole (126c). The pad pattern (112a) is electrically connected with the resistance pattern (116c). Accordingly, as a thickness of a resistor in a region exposed by the resistance contact hole (126c) is increased by the thickness of the pad pattern (112a), it may be possible to secure an adequate margin for the etching process for forming the resistance contact hole (126c). As a result, it may be possible to prevent an insulation phenomenon between a conventional resistance pattern and interconnections.

Furthermore, the pad pattern (112a) in the illustrated embodiments has a lager planar area than that of the region of the resistance pattern (116c) exposed by the resistance contact hole (126c). Due to this, even though the resistance pattern (116c) may be penetrated and the insulating spacer (128) may be formed when the resistance contact hole (126c) is formed, the resistance plug (130c) may still be electrically connected to the pad pattern (112a) and thereby to the resistance pattern (116c). Therefore, it may be possible to prevent insulation between a conventional plug and a resistance pattern.

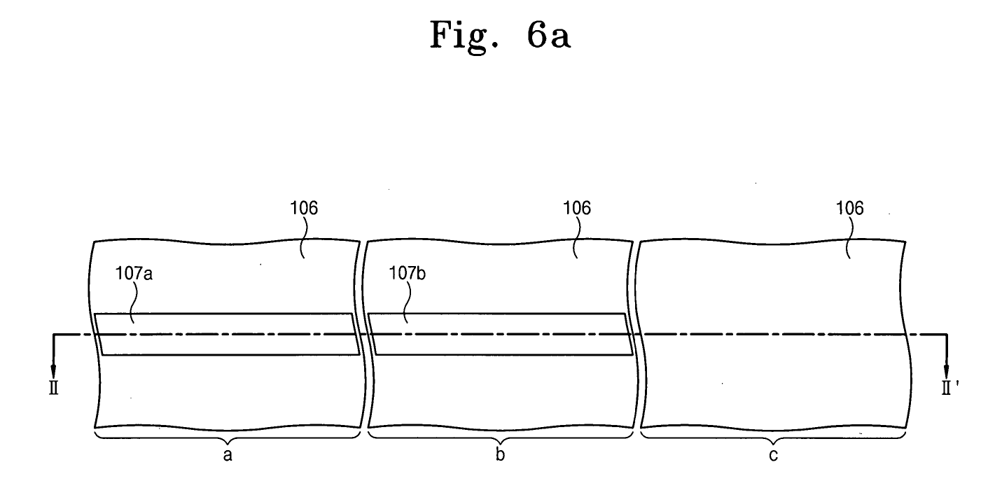

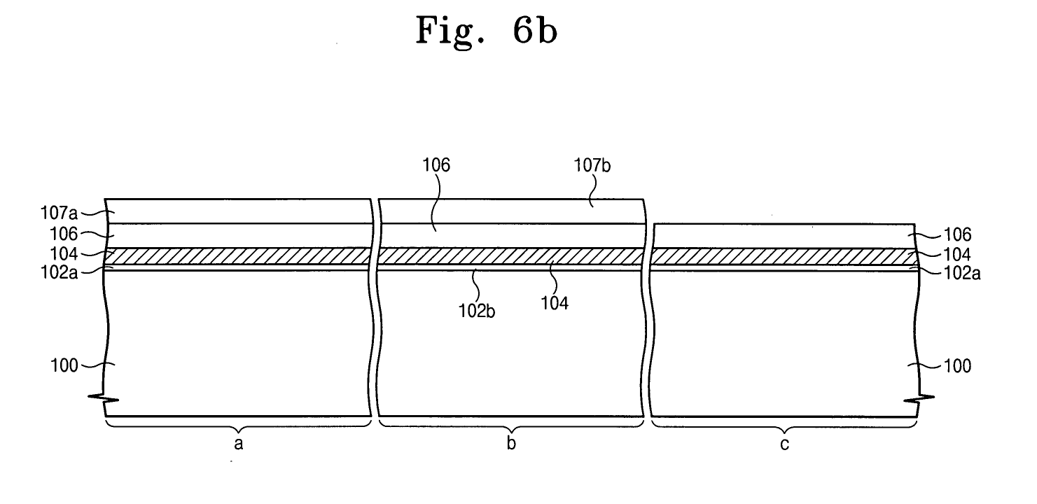

FIGS. 6a through 13a are plan views to illustrate methods for forming a non-volatile memory device in accordance with some embodiments of the present invention. FIGS. 6b, 7b, 8b, 9b, 10b, 11b, 12b and 13b are cross-sectional views taken along the line II-II′ in FIGS. 6a through 13a, respectively.

Referring to FIGS. 6a and 6b, a substrate (100) having a cell region (a), a MOS region (b) and a resistance region (c) is prepared. A tunnel insulating layer (102a) is formed on a substrate (100) in the cell region (a), and a gate insulating layer (102b) is formed on the substrate (100) in the MOS region (b). Either the tunnel and/or gate insulating layers (102a, 102b) may also be formed on the substrate (100) in the resistance region (c). In the drawings, the tunnel insulating layer (102a) is shown formed on the substrate (100) in the resistance region (c).

The tunnel insulating layer (102a) and the gate insulating layer (102b) may be formed to have a different thickness from each other. For example, the gate insulating layer (102b) may be formed to be thicker than the tunnel insulating layer (102a). In this case, an oxidation barrier layer (not shown) for exposing the substrate (100) at the MOS region (b) may be formed on the substrate (100) and a first thermal oxidation process performed. Subsequently, the tunnel and gate insulating layers (102a, 102b) may be formed by removing the oxidation barrier layer after exposing the substrate (100) in the cell and the resistance regions (a, c) and then performing a second thermal oxidation process. Accordingly, the gate insulating layer (102b) may be formed to be thicker than the tunnel insulating layer (102a). In contrast, the tunnel and gate insulating layers (102a, 102b) may be formed to have the same thickness, for example, by performing a single thermal oxidation process.

A first gate conductive layer (104) and a hard mask layer (106) are sequentially formed on an entire surface of the substrate (100) having the insulating layers (102a, 102b). The first gate conductive layer (104) may be formed of doped polysilicon. The hard mask layer (106) may be formed to include an insulating layer having an etch selectivity with respect to the substrate (100) and the first gate conductive layer (104). For example, the hard mask layer (106) may be formed as a single layer of a silicon nitride layer or dual layers of silicon oxide layer and a silicon nitride layer.

First and the second photosensitive film patterns (107a, 107b) are formed on the hard mask layer (106). The first photosensitive film pattern (107a) is formed in the cell region (a), and the second photosensitive film pattern (107b) is formed in the MOS region (b). As seen in FIG. 6b, the hard mask layer (106) in the resistance region (c) remains exposed.

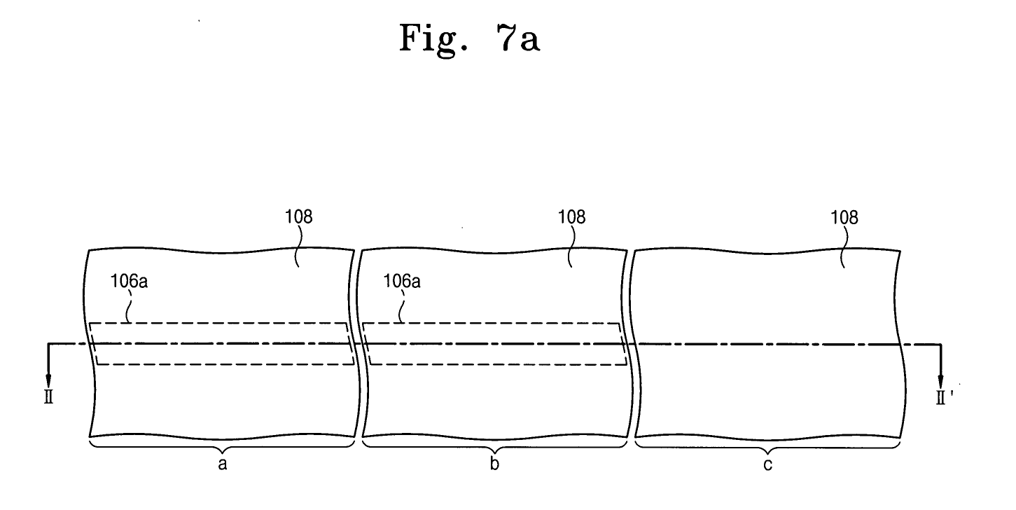

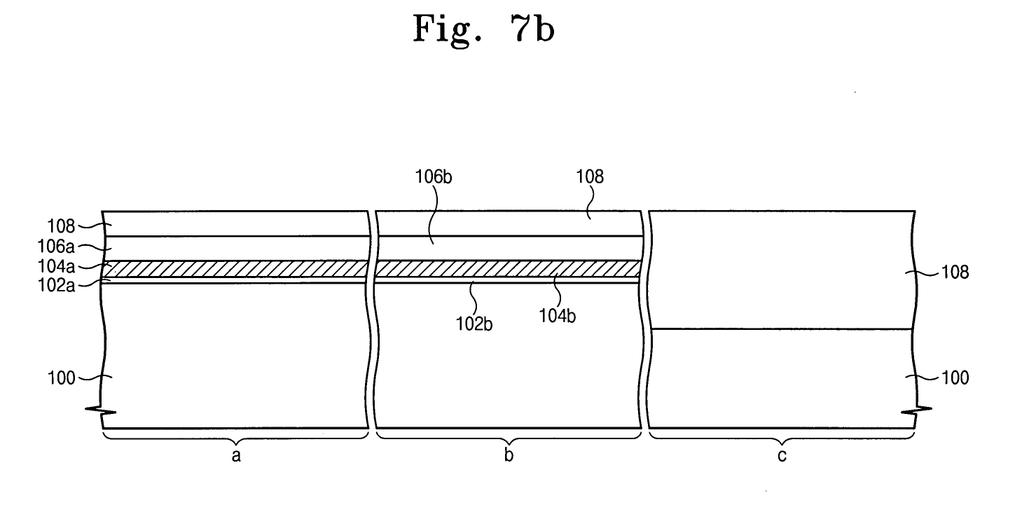

Referring to FIGS. 7a and 7b, the hard mask layer (106) may be anisotropically etched using the first and the second photosensitive film patterns (107a, 107b) as a mask. Accordingly, the first and the second hard mask patterns (106a, 106b) may be formed in the cell and the MOS regions (a, b), respectively. As seen in FIG. 7b, the hard mask layer (106) in the resistance region (b) is removed. The photosensitive film patterns (107a, 107b) are also removed.

A trench for an isolation region is formed in the substrate (100) by consecutively etching the first gate conductive layer (104), the insulating layers (102a, 102b), and the substrate (100) using the hard mask patterns (106a, 106b) as a mask. The trench defines a first active region in the cell region (a), and a second active region (b) in the MOS region (b). At this time, a preliminary floating gate (104a) is formed on the first active region, and a preliminary lower gate (104b) is formed on the second active region. In the resistance region (c), the trench is formed on an entire surface by removing the first gate conductive layer (104) and the tunnel insulating layer (102b).

A device isolation insulating layer (108) for filling the trench is formed on an entire surface of the substrate (100). The device isolation insulating layer (108) may be formed of an insulating layer with a good gap filling characteristic. For example, the device isolation insulating layer (108) may be formed of a HDP silicon oxide layer or/and an SOG layer. Prior to formation of the device isolation insulating layer (108), it is possible to perform a thermal oxidation process to cure an etching damage of the trench. In addition, after an etching damage of the trench is cured, a conformal liner layer (not shown) may be formed.

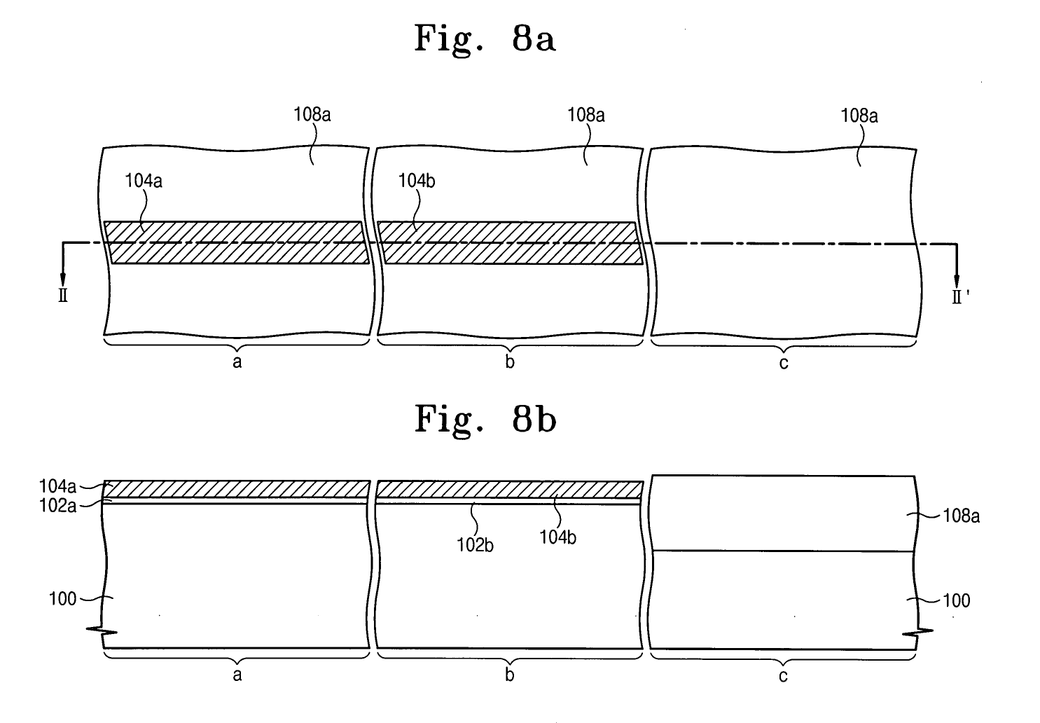

Referring to FIGS. 8a and 8b, a device isolation layer (108a) is formed by planarizing the device isolation insulating layer (108) until the hard mask patterns (106a, 106b) are exposed. The device isolation insulating layer (108) may be planarized by a chemical mechanical polishing (CMP) process. Subsequently, the preliminary floating gate (104a) and the preliminary lower gate (104b) may be exposed by removing the exposed hard mask patterns (106a, 106b).

According to the above described methods, the preliminary floating gate (104a) and a preliminary lower gate (104b) may be formed to be self-aligned on the trench. The trench, the preliminary floating gate (104a) and the preliminary lower gate (104b) may be sequentially formed. In other words, the trench and a device isolation layer (108a) are formed, the tunnel insulating layer (102a) and a gate insulating layer (102b) are formed, a first gate conductive layer is formed on an entire surface of the substrate (100), and the preliminary floating and lower gates (104a, 104b) are formed by patterning the first gate conductive layer.

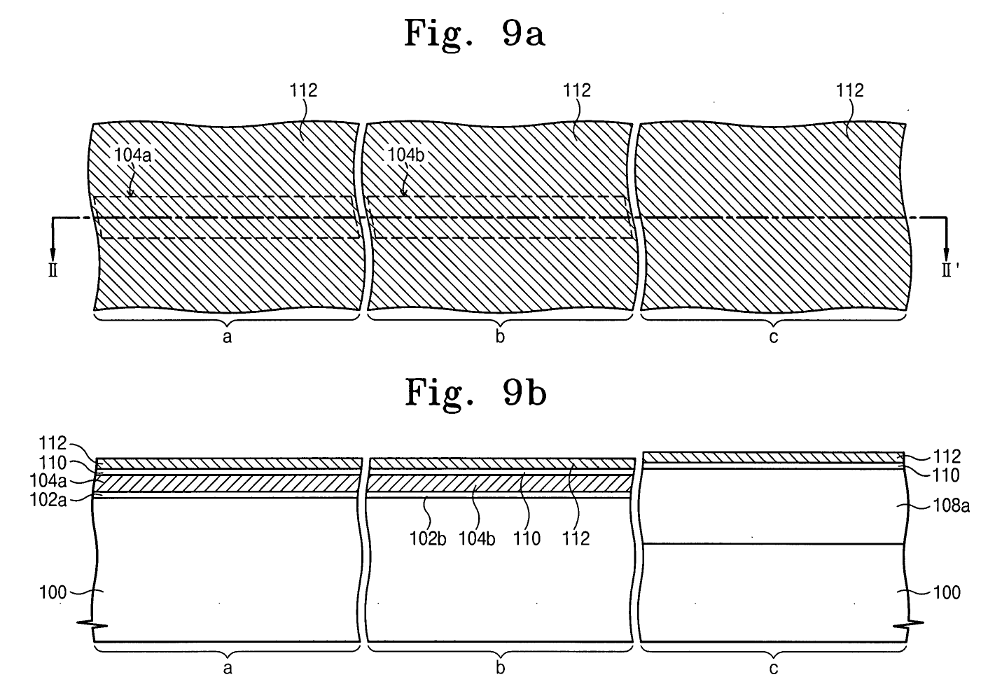

Referring to FIGS. 9a and 9b, a blocking dielectric layer (110) and an etch protection layer (112) are sequentially formed on an entire surface of the substrate (100). The blocking dielectric layer (110) may be formed of an ONO layer. In other embodiments, the blocking dielectric layer (110) may be formed to include a ferroelectric layer having a higher dielectric constant than an ONO layer, for example, a metal oxide layer, such as an aluminum oxide layer and/or a hafnium oxide layer. The etch protection layer (112) may be formed of a material layer capable of protecting the blocking dielectric layer (110) from the etching process. In addition, the etch protection layer (112) may be formed of a material layer that can be used as a resistor. For example, in some embodiments, the etch protection layer (112) is formed of doped polysilicon.

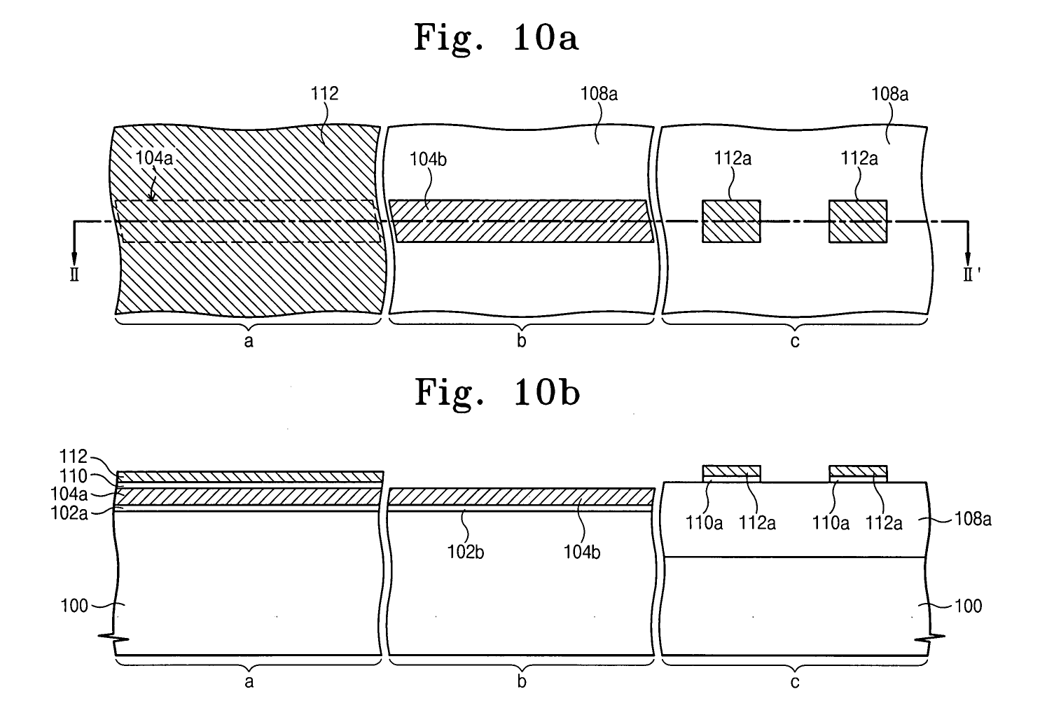

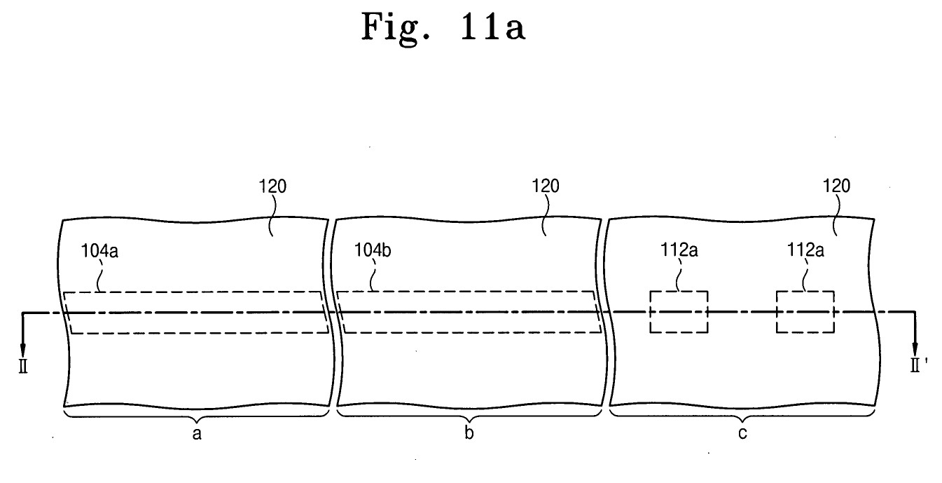

Referring to FIGS. 10a and 10b, the etch protection layer (112) and the blocking dielectric layer (110) at the MOS region (c) may be removed by consecutively patterning the etch protection layer (112) and the blocking dielectric layer (110). Accordingly, the preliminary lower gate (104b) at the MOS region (c) is exposed. At this time, a sequentially stacked insulating pattern (110a) and pad pattern (112a) are formed on a device isolation layer (108a) in the resistance region (c). The insulating pattern (110a) is formed from a part of the blocking dielectric layer (110), and the pad pattern (112a) is formed from a part of the etch protection layer (112). A blocking dielectric pattern (110) and an etch protection layer (112) remain in the cell region (a). The etch protection layer (112) remaining in the cell region (a) may protect the blocking dielectric layer (110) in the cell region (a) from an etching process in the patterning process.

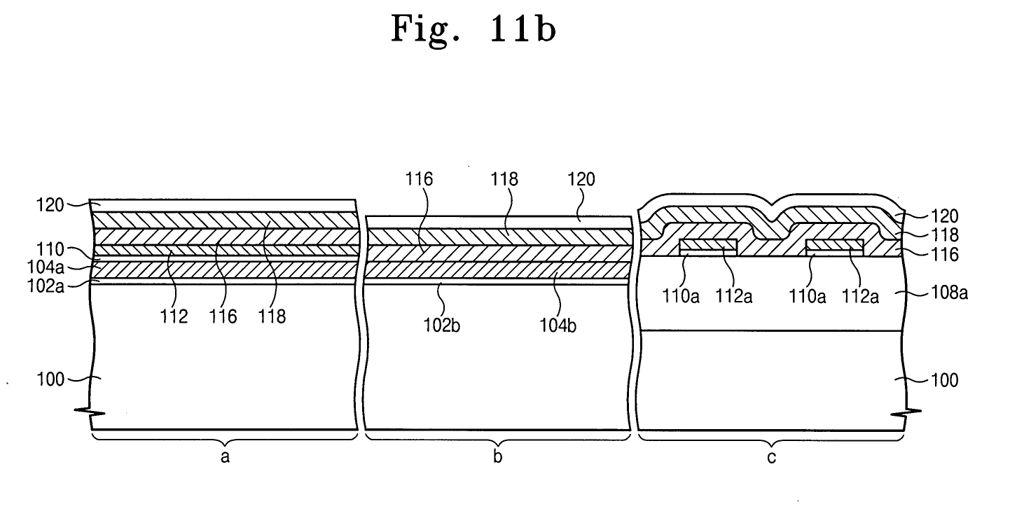

Referring to FIGS. 11a and 11b, a second gate conductive layer (116), a low resistance conductive layer (118), and a capping layer (120) are sequentially formed on an entire surface of the substrate (100) having the pad pattern (112a). The second gate conductive layer (116) is electrically connected to the etch protection layer (112) in the cell region (a), the preliminary lower gate (104b) in the MOS region, and the pad pattern (112a) in the resistance region (c).

In some embodiments, the second gate conductive layer (116) is formed of doped polysilicon. In some embodiments, the low resistance conductive layer (118) is formed of a conductive layer having lower resistivity than doped polysilicon. The low resistance conductive layer (118) may be formed of a single layer or a complex or stacked layer including a material containing a conductive metal. For example, the low resistance conductive layer (118) may be formed of a single layer or a combination of layers selected from a group consisting of or including a metal layer (i.e. tungsten and/or molybdenum), a conductive metal nitride layer (i.e. titanium nitride and/or tantalum nitride), and/or a metal silicide layer (i.e. tungsten silicide, cobalt silicide, nickel silicide and/or titanium silicide, etc.). The capping layer (120) may be formed of a silicon oxide layer, a silicon nitride layer and/or a silicon oxide nitride layer, etc., as an insulating layer.

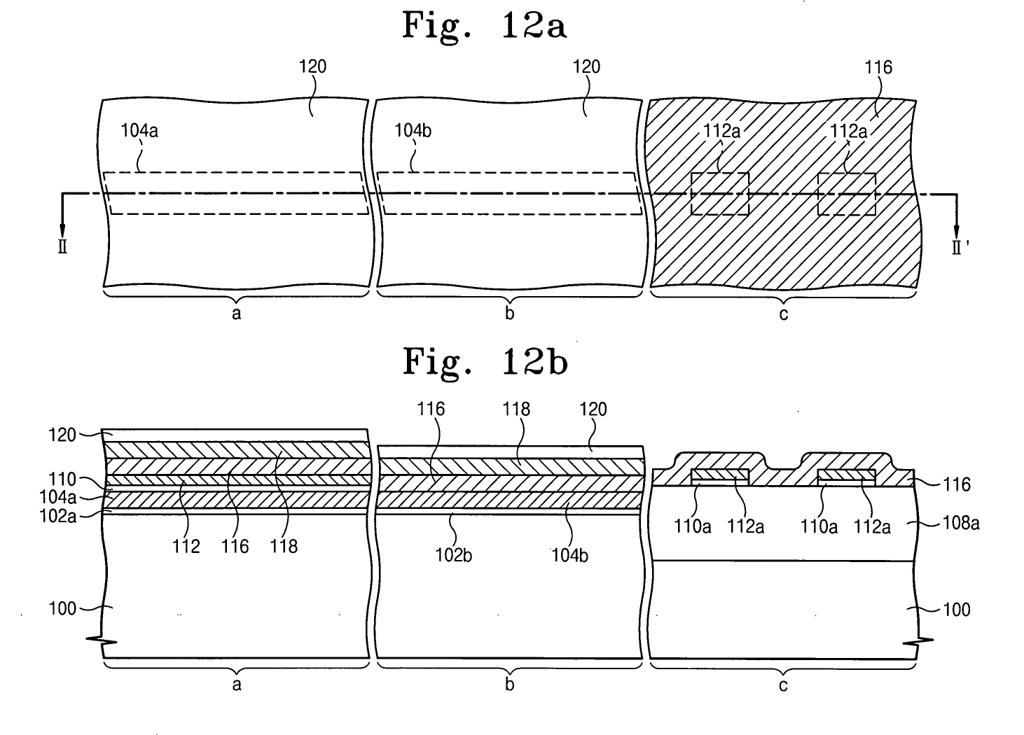

Referring to FIGS. 12a and 12b, the second gate conductive layer (116) in the resistance region (c) is exposed by selectively removing the capping layer (120) and the low resistance conductive layer (118). At this time, the capping layer (120) and the low resistance conductive layer (118) remain in the cell and the MOS regions (a, b). As the low resistance conductive layer (118) includes a conductive metal containing material, it may have an adequate etch selectivity with respect to the second gate conductive layer (116) formed of doped polysilicon.

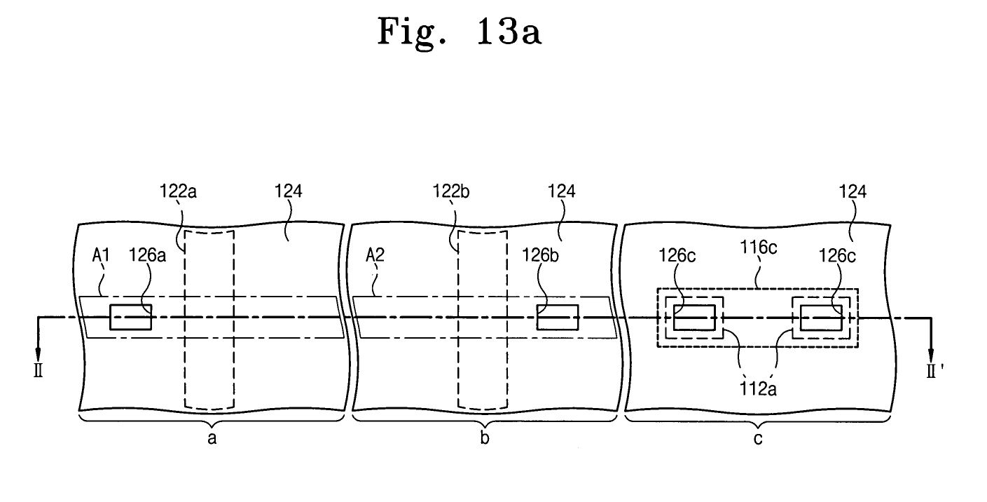

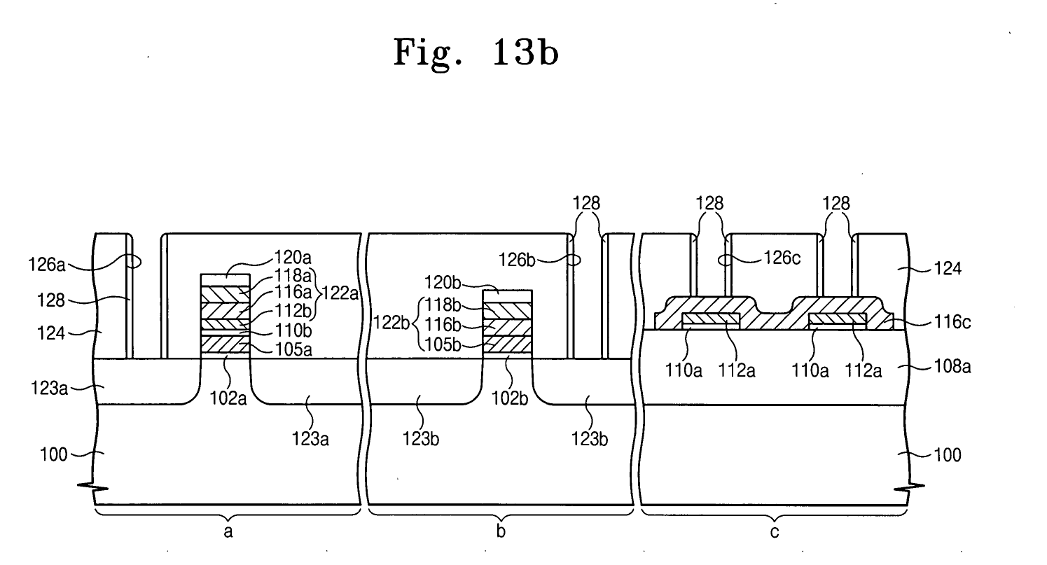

Referring to FIGS. 13a and 13b, a sequentially stacked floating gate (105a), blocking dielectric pattern (110b), control gate electrode (122a) and first capping pattern (120a) may be formed by consecutively patterning the capping layer (120), the low resistance conductive layer (118), the second gate conductive layer (116), the etch protection layer (122), the blocking dielectric layer (110) and the preliminary floating gate (104a) in the cell region (a). The control gate electrode (122a) in the illustrated embodiments includes the etch protection pattern (112b), the gate conductive pattern (116a) and the first low resistance pattern (118a), which are sequentially stacked. The gate conductive pattern (116a) is formed of a part of the second gate conductive layer (116a). In FIG. 13a, the reference numerals “A1” and “A2” indicate the first active region (A1) and the second active region (A2), respectively. The control gate electrode (122a) crosses the first active region (A1).

A sequentially stacked MOS gate electrode (122b) and second capping pattern (120b) are formed by consecutively patterning the capping layer (120), the low resistance conductive layer (118), the second gate conductive layer (116) and the preliminary lower gate (104b) in the MOS region (b). The MOS gate electrode (122b) crosses the second active region (A2). The MOS gate electrode (122b) in the illustrated embodiments includes the lower gate (105b), the upper gate (116b) and the second low resistance pattern (118b), which are sequentially stacked. The upper gate (116b) is formed of a part of the second gate conductive layer (116). The lower gate (105b) may be electrically connected to the upper gate (116b) by removing the blocking dielectric layer (110) in the MOS region (b) using the etch protection layer (112). As such, the MOS gate electrode (122b) may provide a gate of a MOS transistor.

If the blocking dielectric layer (110) remains in the MOS region (b), the lower gate (105b) may be insulated from the upper gate (116b) and be floated. In this case, problems may occur wherein a threshold voltage of the MOS transistor increases and the MOS transistor may be soft-programmed. These problems may be reduced or even eliminated by removing the blocking dielectric layer (110) in the MOS region (b) using the etch protection layer (112).

A resistance pattern (116c) for covering the pad pattern (112a) may be formed by patterning the second exposed gate conductive layer (116) in the resistance region (c). The pad pattern (112a) is disposed below both edges of the resistance pattern (116c), respectively. In other words, the resistance pattern (116c) covers the pad pattern (112a) including an upper and sidewall surfaces thereof. The pad pattern (112a) is electrically connected to the resistance pattern (116c). In some embodiments, the processes for patterning the control gate electrode (122a), the MOS gate electrode (122b), and the resistance pattern (116c) are simultaneously performed. In other embodiments, the control gate electrode (122a), the MOS gate electrode (122b), and the resistance pattern (116c) are formed sequentially. As the gate conductive pattern (116a), the upper gate (116b) and the resistance pattern (116c) are formed from the second gate conductive layer (116) in some embodiments, they are formed of the same material.

The first impurity dope layer (123a) is formed in the first active region (A1) at both sides of the control gate electrode (122a) and the second impurity doped layer (123b) is formed at both sides of the MOS gate electrode (122b). The second impurity doped layer (123b) corresponds to a source/drain region of a MOS transistor. The first and the second impurity doped layers (123a, 123b) may be formed sequentially or simultaneously. In addition, the first and the second impurity doped layers (123a, 123b) may be doped with the same and/or different impurities. Although not shown, in some embodiments, the cell or/and the second impurity doped layers (123a, 123b) are formed to have an LDD structure and/or an extended source/drain structure, for example, by forming a gate spacer (not shown) at sidewalls of the control gate electrode (122a) and the MOS gate electrode (122b), and injecting additional impurity ions.

The interlayer insulating layer (124) is formed on an entire surface of the substrate (100). The interlayer insulating layer (124) may be formed of a silicon oxide layer.

The cell contact hole (126a) for exposing the first impurity doped layer (123a), the MOS contact hole (126b) for exposing the second impurity doped layer (123b) and the resistance contact hole(s) (126c) for exposing the resistance contact pattern (116c) are formed by patterning the interlayer insulating layer (124). The resistance contact hole (126c) exposes the resistance pattern (116c) disposed on the pad pattern (112a). In some embodiments, a planar area of the pad pattern (112a) is greater than that of the region of the resistance pattern (116c) exposed by the resistance contact hole (126c). The contact holes (126a, 126b, 126c) may be formed simultaneously and/or sequentially.

In some embodiments, the cell contact hole (126a) may be omitted. For example, in a case of a NAND-type non-volatile memory device, the cell contact hole (126a) may not be needed.

The insulating spacer(s) (128) may be formed on inner sidewalls of the contact holes (126a, 126b, 126c). The insulating spacer(s) (128) may be formed of an insulating layer, such as a silicon oxide layer, a silicon nitride and/or a silicon oxide nitride layer.

Subsequently, plugs (130a, 130b, 130c) shown in FIG. 5b are formed to fill the contact holes (126a, 126b, 126c). The non-volatile memory device shown in FIGS. 5a and 5b may be provided by forming the interconnections (132a, 132b, 132c) shown in FIGS. 5a and 5b to connect to the plugs (130a, 130b, 130c), respectively.

In some embodiments of methods for forming the above described non-volatile memory device, the pad pattern (112a) is formed below a resistance pattern (116c) that is exposed by the resistance contact hole (126c). Accordingly, a thickness of a resistor may be increased in a region where the resistance contact hole (126c) is formed. As a result, it may be possible to prevent an insulation layer from being formed between the resistance plug (130c) and the resistance pattern (116c) while securing an adequate margin for an etching process for forming the contact holes (126a, 126b, 126c).

In addition, a planar area of the pad pattern (112a) may be greater than that of the region of the resistance pattern (116c) exposed by the resistance contact hole (126c). Accordingly, even though the resistance pattern (116c) may be penetrated and the insulating spacer (128) may be formed when the contact holes (126a, 126b, 126c) are formed, the resistance plug (130c) may still be connected to the pad pattern (112a). As a result, the resistance plug (130c) may be electrically connected to the resistance pattern (116c) by way of the pad pattern (112a).

Furthermore, the pad pattern (112a) may be formed out of the etch protection layer (112) that is formed so as to remove a blocking dielectric pattern (110) in the MOS region (b). In other words, a process for forming the pad pattern (112a) may be performed at the same time as the process for removing a blocking dielectric layer (110) and an etch protection layer (112) in the MOS region (b) is performed. Accordingly, no additional processes may be required in forming the pad pattern (112a). As a result, it may be possible to reduce or even prevent a drop of productivity from defective devices in forming non-volatile memory devices.

As described above, according to some embodiments of the present invention, a pad pattern is disposed below a resistance pattern exposed by a resistance contact hole. The pad pattern is electrically connected to the resistance pattern. As such, a resistor defined thereby may have an increased thickness at a portion where a resistance contact is formed. This may secure a greater margin for an etching process for forming contact holes. As a result, it may be possible to prevent insulation between a resistance plug in the resistance contact hole and the resistance pattern from adversely affecting the electrical connection therebetween.

In addition, a planar area of the pad pattern in some embodiments is greater than that of the region of the resistance pattern exposed by the resistance contact hole. Even if the resistance pattern is penetrated and an insulating spacer is formed on an inner sidewall of the resistance contact hole when a contact hole is formed, the resistance plug may be electrically connected to the resistance pattern by way of the pad pattern. As a result, it may be possible to prevent insulation from adversely affecting the electrical connection between a conventional plug and a resistance pattern.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A memory device comprising:
a semiconductor substrate;
a device isolation layer in the substrate and defining a cell region and a resistance region;
a resistance pattern disposed on the device isolation layer in the resistance region; an interlayer insulating layer on the resistance pattern;
a resistance contact hole with a contact plug therein extending through the interlayer insulating layer and exposing the resistance pattern; and
a conductive pad pattern interposed between the resistance pattern and the device isolation layer that is electrically connected to the resistance pattern, the conductive pad pattern being positioned between the resistance contact hole and the device isolation layer and having a planar area greater than a planar area of the resistance pattern exposed by the resistance contact hole, the conductive pad pattern and the resistance pattern defining a resistor of the memory device having a greater thickness in a region including the conductive pad pattern.

2. The memory device of claim 1, wherein the resistance contact hole comprises a first contact hole having a first contact plug therein and a second contact hole displaced from the first contact hole and having a second contact plug therein and wherein the conductive pad pattern comprises a first region between the first contact hole and the device isolation layer and a separate second region between the second contact hole and the device isolation layer and wherein the resistor has a smaller thickness in a region between the first and second region of the conductive pad pattern than in regions including the conductive pad pattern and wherein the memory device further comprises:
a first conductive interconnection extending on the interlayer insulating layer in the resistance region and electrically contacting the first contact plug; and
a second conductive interconnection extending on the interlayer insulating layer in the resistance region and electrically contacting the second contact plug.

3. The memory device of claim 2, wherein the memory device comprises a non-volatile memory device including a floating gate in the cell region having a control gate electrode thereon with an etch protecting conductive layer therebetween and wherein the etch protecting conductive layer and the conductive pattern are formed in a same layer and wherein the memory device further comprises insulating spacers between sidewalls of the resistance contact holes and the contact plugs therein.

4. A non-volatile memory device comprising:
a device isolation layer in a substrate, the device isolation layer defining a cell region and having a resistance region thereon;
a floating gate on an active region of the cell region defined by the device isolation layer;
a blocking dielectric pattern on the floating gate;
a control gate electrode on the blocking dielectric pattern, the control gate electrode including an etch protection pattern;
a resistance pattern disposed on the device isolation layer in the resistance region; and
a pad pattern interposed between the resistance pattern and the device isolation layer and electrically connected to the resistance pattern, wherein the pad pattern and the etch protection pattern are formed of the same material.

5. The device of claim 4, further comprising a tunnel insulating layer and wherein:
the tunnel insulating layer, the floating gate and the blocking dielectric pattern are sequentially stacked on the active region of the cell region defined by the device isolation layer; and
the control gate electrode includes the etch protection pattern, a gate conductive pattern and a low resistance pattern, which are sequentially stacked.

6. The device of claim 5, further comprising:
an interlayer insulating layer covering a surface of the substrate in the cell region and the resistance region;
a contact hole penetrating the interlayer insulating layer and exposing a portion of the resistance pattern that is disposed on the pad pattern; and
a plug filling the contact hole.

7. The device of claim 6, wherein a planar area of the pad pattern is greater than a planar area of the portion of the resistance pattern that is exposed by the contact hole.

8. The device of claim 6, further comprising an insulating spacer disposed on an inner sidewall of the contact hole.

9. The device of claim 5, wherein the resistance pattern is formed of the same material as the gate conductive pattern.

10. The device of claim 5, further comprising:
an insulating pattern interposed between the pad pattern and the device isolation pattern, and
wherein the insulating pattern is formed of the same material as the blocking dielectric pattern.

11. The device of claim 5, wherein the substrate further includes a MOS region, the device further comprising:
a gate insulating layer formed on a second active region defined by the device isolation layer in the MOS region;
a MOS gate electrode on the gate insulating layer, the MOS gate electrode including a lower gate, an upper gate and a second low resistance pattern sequentially stacked on the gate insulating layer.

12. The device of claim 11, further comprising:
a first impurity doped layer formed in the first active region at both sides of the control gate electrode;
a second impurity doped layer formed in the second active region at both sides of the MOS gate electrode; an interlayer insulating layer covering a surface of the substrate in the cell region, the MOS region and the resistance region;
a MOS contact hole penetrating the interlayer insulating layer and exposing the second impurity doped layer;
a MOS plug filling the MOS contact hole;
a resistance contact hole penetrating the interlayer insulating layer and exposing a portion of the resistance pattern that is disposed on the pad pattern; and a resistance plug filling the resistance contact hole.

13. The device of claim 12, wherein a planar area of the pad pattern is greater than a planar area of the portion of the resistance pattern that is exposed by the resistance contact hole.

14. The device of claim 12, further comprising an insulating spacer disposed on an inner sidewall of the MOS contact hole and on an inner sidewall of the resistance contact hole.

15. The device of claim 11, wherein the resistance pattern, the gate conductive pattern and the upper gate are formed of the same material.

16. The device of claim 11, further comprising an insulating pattern interposed between the pad pattern and the device isolation layer, wherein the insulating pattern is formed of the same material as the blocking dielectric pattern.

17. A method for forming a non-volatile memory device, the method comprising:
forming a device isolation layer in a substrate defining a cell region of the substrate and having a resistance region of the substrate thereon;
forming a floating gate on an active region of the cell region defined by the device isolation layer;
forming a blocking dielectric pattern on the floating gate;
forming a control gate electrode including an etch protection pattern on the blocking dielectric pattern; and
forming a pad pattern on the device isolation layer in the resistance region, wherein the pad pattern is formed of the same material as the etch protection pattern; and
forming a resistance pattern disposed on the device isolation layer in the resistance region, the resistance pattern covering the pad pattern and being electrically connected to the pad pattern.

18. The method of claim 17, wherein forming the floating gate is preceded by forming a tunnel insulating layer on the active region of the cell region and wherein forming the floating gate comprises forming the floating gate on the tunnel insulating layer and wherein forming the control gate electrode comprises:
forming the etch protection layer;
forming a gate conductive pattern on the etch protection layer; and
forming a low resistance pattern on the gate conductive pattern.

19. The method of claim 18, further comprising:
forming an interlayer insulating layer covering a surface of the substrate in the cell region and the resistance region;
forming a contact hole penetrating the interlayer insulating layer and exposing a portion of the resistance pattern that is disposed on the pad pattern; and
forming a plug filling the contact hole.

20. The method of claim 19, wherein a planar area of the pad pattern is greater than a planar area of the portion of the resistance pattern that is exposed by the contact hole.

21. The method of claim 19, wherein forming the plug is preceded by forming an insulating spacer on an inner sidewall of the contact hole.

22. The method of claim 18, wherein forming the floating gate, forming the blocking dielectric pattern, forming the control gate electrode, forming the pad pattern and forming the resistance pattern comprises:
forming a preliminary floating gate on the tunnel insulating layer; forming a blocking dielectric layer and an etch protection layer sequentially on the substrate;
patterning the etch protection layer and the blocking dielectric layer to form an insulating pattern and the pad pattern sequentially stacked in the resistance region while leaving the blocking dielectric layer and the etch protection layer in the cell region;
sequentially forming a gate conductive layer and a low resistance conductive layer on the substrate;
exposing the gate conductive layer in the resistance region by selectively removing the low resistance conductive layer;
sequentially patterning the low resistance conductive layer, the gate conductive layer, the etch protection layer, the blocking dielectric layer and the preliminary floating gate of the cell region, to form the floating gate, the blocking dielectric pattern and the control gate electrode; and
forming the resistance pattern by patterning the exposed gate conductive layer in the resistance region.

23. The method of claim 18, wherein forming the device isolation layer further comprises forming a device isolation layer defining a MOS region of the substrate, the method further comprising:
forming a gate insulating layer on a second active region defined by the device isolation layer in the MOS region; and
forming a MOS gate electrode on the gate insulating layer, including:
forming a lower gate on the gate insulating layer;
forming an upper gate on the lower gate; and
forming a second low resistance pattern on the upper gate.

24. The method of claim 23, further comprising:
forming a first impurity doped layer in the first active region at both sides of the control gate electrode;
forming a second impurity doped layer in the second active region at both sides of the MOS gate electrode;
forming an interlayer insulating layer covering a surface of the substrate in the cell region, the MOS region and the resistance region;
forming a MOS contact hole penetrating the interlayer insulating layer and exposing the second impurity doped layer;
forming a resistance contact hole penetrating the interlayer insulating layer and exposing a portion of the resistance pattern that is disposed on the pad pattern;
forming a resistance plug filling the resistance contact hole; and forming a MOS plug filling the MOS contact hole.

25. The method of claim 24, wherein a planar area of the pad pattern is greater than a planar area of the portion of the resistance pattern that is exposed by the resistance contact hole.

26. The method of claim 24, wherein forming the resistance plug and forming the MOS plug are preceded by forming an insulating spacer on an inner sidewall of the resistance contact hole and on an inner sidewall of the MOS contact hole.

27. The method of claim 23, wherein the forming the floating gate, the blocking dielectric pattern, the control gate electrode, the MOS gate electrode, the pad pattern and the resistance pattern comprises:
forming a preliminary floating gate on the first active region; forming a preliminary lower gate on the second active region;
forming a blocking dielectric layer on the substrate; forming an etch protection layer on the blocking dielectric layer;
sequentially patterning the etch protection layer and the blocking dielectric layer to form a sequentially stacked insulation pattern and pad pattern on the device isolation layer in the resistance region and to remove the etch protection layer and the blocking dielectric layer in the MOS region while leaving the etch protection layer and the blocking dielectric layer in the cell region;
forming a gate conductive layer on the substrate; forming a low resistance conductive layer on the gate conductive layer;
exposing the gate conductive layer in the resistance region by selectively removing the low resistance conductive layer;
sequentially patterning the low resistance conductive layer, the gate conductive layer, the etch protection layer, the blocking dielectric layer and the preliminary floating gate in the cell region to form the floating gate, the blocking dielectric pattern and the control gate electrode;
sequentially patterning the low resistance conductive layer, the gate conductive layer and the preliminary lower gate in the MOS region to form the MOS gate electrode; and
patterning the exposed gate conductive layer in the resistance region to form the resistance pattern.
